(19) United States
(12) Patent Application Publication
(10) Pub. No.: US 2012/0092202 A1
(43) Pub. Date: Apr. 19, 2012

(54) ANALOG TO DIGITAL CONVERTER

(76) Inventors: Nikolaos Petrellis, Achaia (GR); Michael Birbas, Achaia (GR); John Kikidis, Achaia (GR)

(21) Appl. No.: 13/060,720

(22) PCT Filed: Sep. 1, 2009
(86) PCT No.: PCT/GB09/51101

§ 371 Date: Feb. 25, 2011

(30) Foreign Application Priority Data
Aug. 29, 2008 (GB) 0815802.4

(51) Int. Cl. H03M 1/12

(52) U.S. Cl. 341/155

(57) ABSTRACT

An analog to digital converter for converting an initial analog signal into a digital signal comprising at least one electronic module with an input, a first output, and a second output, which module generates from an analog input signal: a first output signal, which first output signal in terms of multiples of a predetermined amount of current or voltage, such as 1 uA or 1 mV, is substantially equal to the integer quotient of division of the input signal by a number or comprises a plurality of signals which if combined are substantially equal to the integer quotient of division of the input signal in terms of multiples of a predetermined amount of current or voltage, and a second output signal which in terms of multiples of a predetermined amount of current or voltage, such as 1 uA or 1 mV, is substantially equal to the remainder of the division, the analog to digital converter also comprising a further analog to digital converter for converting the second output signal into a digital signal, wherein the further analog to digital converter is connected the at least one module and the module is configured so that in use when the analog input signal connects through the input the first output signal connects through the first output, and the second output signal connects through the second output into the further analog to digital converter.

### BACKGROUND OF THE INVENTION

1. Field of the Invention

The present invention relates to Analog to Digital Converters that operate either in current mode in order to perform several mathematical operations such as addition, subtraction, multiplication and division in a simple way or in voltage mode in order to achieve higher speeds. It furthermore relates to an integer divider/floor function provider/quantizer. Moreover, lower power supply can be used in current mode operation and the speed may be comparable to that of a flash converter if fast current comparators are used.

2. Description of Related Art

The fastest commonly used Analog to Digital Converters are so called Flash ADCs. If a Flash converter has n-bit resolution, it requires 2ⁿ comparators that accept as input the sampled voltage and compare it to 2ⁿ referencevoltages provided by a resistor ladder. The comparator outputs (also referred to as thermometer or unary code) are encoded to provide a n-bit binary output. This encoding requires exclusive and inclusive OR operations that can be implemented as described for example in the paper authored by F. Liu et al, entitled “CMOS Folding and Interpolating ADC with Differential Compensative Track and Hold Circuit” that was presented in the IEEE Conference on Electron Devices and Solid State Circuits, December 2003, pp. 453-456. The Flash architecture can also be applied to current mode ADCs. For example, in prior art in the Proceedings of the 44th IEEE MWSCAS, Volume 1, 14-17 Aug. 2001 Page(s): 272-275 vol. 1 entitled “CMOS current mode flash analog to digital converter”, authored by Bell, J. A., Bruce, J. W., Blalock, B. J. and Stubberud, P. A. describes the 2ⁿ current comparators working in current mode comparing the input current (derived by a Voltage to Current converter) to 2ⁿ reference currents. Flash converters with higher than 8-bit resolution, are not practically used, due to the large number of comparators they consist of and consequently their high power consumption and required area.

Pipeline and Subrange current mode ADCs such as the one described for example in the Proceedings of IEEE ISCAS 2002 Volume 3, 26-29 May 2002 Page(s): III-117-111-120 vol. 3, by Yu-Yee Liow and Chung-Yu Wu in the work entitled “The design of high-speed pipelined analog-to-digital converters using voltage-mode sampling and current mode processing techniques” consist of a sequence of lower resolution ADCs. For example a 2-stage m+n bit subrange ADC consists of a m-bit coarse conversion followed by a n-bit fine conversion stage. The m-most significant bits of the coarse ADC are input to a Digital to Analog Converter (DAC) and the output of this DAC is subtracted by the initial signal. The difference feeds the input of the n-bit fine ADC. The size of the coarse ADC can be larger than m bits (e.g., m+r). The redundant r-bits can be used by correction logic to correct errors derived from noise and transistor mismatches. The redundant r-least significant bits of the coarse ADC should match the r-most significant bits of the n-bit fine ADC (r<n).

The number of comparators used in pipeline ADCs is significantly smaller than the ones required by a flash one with the same resolution. More specifically a flash n+m bits ADC requires 2^{n+m} comparators while a two stage pipeline ADC (without correction logic) requires 2ⁿ+2^{m} ones. This number can be further reduced if more stages are used with smaller number of bits per stage. The Sample and Hold circuits needed at each stage are synchronized by one or more clock signals. The pipeline ADCs offer high throughput due to the fact that each stage operates on a different sample. Nevertheless, the latency for completing a single conversion is orders of magnitude higher than that required by a flash ADC.

Folding and Interpolating converters such as the one described in the IEEE Journal of Solid State Circuits, Vol. 38, No. 8, August 2003, pages: 1405-1410, in the paper entitled “A Wide Input Bandwidth 7-bit 300 MS/s Folding and Current-Mode Interpolating ADC”, authored by Yiunchu Li and Edgar Sanchez Sinencio, use less than 2ⁿ comparators for a n-bit ADC. The input is compared successively to different sets of references that are applied to the comparators.

Current mode implementations rely heavily on high speed current comparators. Such high speed comparators are disclosed in the prior art described in the previous paragraphs or in the US patent US2002/0105363 A1 authored by Lin et al. The convergence delay of this comparator depends on the input current and ranges from less than 1 ns to 100 ns for an input current between 10 uA to 0.01 uA respectively.

The selection of a fast comparator is also important for voltage mode implementations. The fastest known voltage mode comparators described in the literature are differential comparators. The comparator followed by a D Flip Flop latch that is described in the paper entitled “A 3.5 GS/s 5-b Flash ADC in 90 nm CMOS” that was presented in IEEE 2006 Custom Integrated Circuits Conference (CICC), pp. 489-492, authored by S. Park et al, can be mentioned as an example. Another example of a fast differential voltage comparator is described in the patent CN101346880 (A)/2009-01-14 authored by J. Naka and K. Sushihara.

The input of a current mode ADC should be supplied through a Sample and Hold (S/H) circuit followed by a Voltage to Current (V2I) converter. Similar approaches to the one disclosed in the present invention can be found in the IEEE Transactions on Circuits and Systems II, Vol. 1, January 1998, pages: 61-75, in the paper entitled “An integrated 200 MHz 3.3V BiCMOS class-IV partial-response analog Viterbi decoder”, authored by Shakiba, M., Johns, D. and Martin, K. as well as in the IEEE Journal of Solid-State Circuits, Vol. 40, No. 3, March 2005, pages 753-762, in the paper entitled “A 0.35-μm CMOS Analog Turbo Decoder for the 40-bit Rate 1/3 UMTS Channel Code”, authored by Vogrig, D., Gerosa, A., Neviani, A., Grael i Amat, A., Montorsi, G. and Benedetto, S.

### SUMMARY OF THE INVENTION

An object of the present invention is to provide an ADC circuit that mitigates at least one the problem with the prior art mentioned above and preferably is capable of performing high resolution Analog to Digital Conversion with a small number of components requiring small area and low power consumption without sacrificing speed.

According to a first aspect of the invention there is provided an analog to digital converter for converting an initial analog signal into a digital signal comprising, a plurality of electronic modules with an input a first output and a second output which modules generate from an analog input current (or voltage), a first output current (or voltage) which in terms of multiples of a predetermined amount of current (or voltage), such as 1 uA, (or 1 mV) is substantially equal to the integer quotient of division of the input current (or voltage) by a number, and, a second output current (or voltage) which in terms of multiples of a predetermined amount of current (or voltage), such as 1 uA, (or 1 mV) is substantially equal to the remainder of the division, the module configured so that in use when the analog input current (or voltage) enters through the input the first output current (or voltage) exits from the first output the second output current (or voltage) exits from the second output and, wherein the modules are configured in a tree formation connected together, the formation comprising, an input module with the first and second outputs each connected a different module, the input module configured so that in use it takes the initial analog input and sends the first and second output current (or voltage) to the two connected modules, and an output layer comprising at least two modules, one connected to a first output of another module and one to a second output of a module, wherein in use when the output currents (or voltages) of the modules of the output layer are mapped to a binary value by comparison to a threshold value (current or voltage) they provide the digital signal.

Preferably for at least one, and more preferably each, module the predetermined current (or voltage) for the first and second outputs is the same and/or wherein the predetermined current (or voltage) for a first or second output of one or more/each module is the same.

Preferably the number of the division is in the form 2^{x} where x is an integer and/or wherein if the outputs currents (or voltages) of a/each modules are mapped to a binary value by comparison to a threshold current (or voltage). the/each modules act as two bit resolution analog to digital converter of the input current (or voltage) received at that module's input,

Preferably wherein there is at least one intermediate layer of modules between the input layer and at least some/one of the modules of the output layer. More preferably wherein there are a plurality of intermediate layers of modules between the input layer and at least some of the modules of the output layer and/or wherein the first intermediate layer comprising at least two modules each of the two taking an output current (or voltage) from the input module to its input and any subsequent layers taking the output currents (or voltages) of the previous layer to its input and providing its output currents (or voltages) to the next layer which in the case of the last intermediate layer is the output layer.

Preferably wherein integer x for the number used for division by a module is one greater than integer x for the number used for division by the modules connected to one or both of its outputs and/or x is equal to one for at least one and possibly all of the modules in the output layer and/or wherein the output layer comprises n/2 modules where n is the bits of resolution of the converter

Preferably the converter comprising a mapper configured to map output currents (or voltages) of the modules of the output layer to a binary value by comparison to a threshold current (or voltage) to provide the digital signal and/or wherein one or more and preferably each module comprises an integer divider which divides an input current (or voltage) by the number, and provides the integer quotient, optionally a multiplier which multiplies an input current (or voltage) by the number of the division, and a subtractor which takes one input current (or voltage) from another, the components arranged so that in use the integer divider supplies the first output current or voltage (multiplier receives its input from the integer divider) and the subtractor receives its inputs from the multiplier or the integer divider, and from the module input.

According to an aspect of the invention there is provided an integer divider for finding the integer quotient of dividing by a number y, the divider comprising y−1 comparators and y−1 connected switches,

each comparator comparing an input current to a multiple of a reference current the multiple of the reference current varying from one to y−1 for the comparators, and preferably including each integer in between,

the y−1 switches each connected to a comparator output and a predetermined current which depending on the output of the comparator either allow the predetermined current to pass or do not,

the output is combined from the predetermined current allowed to pass and is equal to the integer quotient of the input current divided by the number expressed in multiples of predetermined current.

Preferably the predetermined current of an integer divider is the reference current divided in amplitude by y and/or the predetermined current is the reference current and/or, the predetermined current used is such that the integer quotient of the input current expressed in multiples of predetermined current is of same magnitude as input and/or is the result of a floor function applied to the input current

Preferably an integer divider for dividing by a number z where z=ab comprises a first integer divider with a−1 comparators (where a=y) and a second comprising b−1 comparators (where b=y) connected together preferably so that the output of the first divider is subtracted from the input current and the result is sent as the input current of the second divider, the outputs currents of the first and second dividers being added together to form the output current of the overall integer divider.

There may be provided an analog to digital converter for converting an initial analog voltage into a digital signal comprising a voltage to current converter and a analog to digital current converter

According to an aspect of the invention there is provided an analog to digital converter comprising a binary tree of 2 bit resolution analog to digital converters with the inputs of some converters connected to the outputs of others.

Further aspects and preferable features of the invention are defined in the claims.

In some embodiments there may be provided a DIVNxIu circuit performing integer division of an input current Iin with a reference current Iref. The current unit is Iu. The output of DIVNxIu is a current nIu, where n is the highest positive integer with nIref≦Iin. This circuit can be used to perform the integer division or the floor function on a floating point current value. DIVNxIu may consists of N−1 current comparators, N−1 current sources of Iu and N−1 switches. The input Iin can be compared at each one of the N−1 current comparators with the reference currents Iref, 2Iref, . . . , (N−1)Iref. The output of each current comparator controls a corresponding switch. The input of each switch is connected to a current source Iu. The outputs of the switches are connected together to form the output of the DIVNxIu component. The implementation of a DIVNxIu component can be based on N and P current mirrors. In N-current mirrors all the input and output currents flow into the mirror. The N-current mirrors can be implemented for example with NMOS transistors in the case that CMOS technology is used or NPN transistors in the case that bipolar technology is employed. In P-current mirrors all the input and output currents flow outside of the mirror. The P-current mirrors can be implemented for example with PMOS transistors in CMOS technology or PNP transistors in bipolar technology. The said DIVNxIu circuit preferably comprises N−1 current comparators; A current copier circuit capable of producing N−1 copies of the input current. The current copier consists of an N-current mirror with N−1 outputs that are connected to the first input of the said current comparators. Each output of the current mirror should reproduce the exact input current;

A current copier-and-multiplier circuit capable of producing the N−1 currents: Iref, 2Iref, . . . , (N−1)Iref. The current copier-and-multiplier preferably consists of a P-current mirror with N−1 outputs. The input of the current mirror is connected to the current source Iref. For example, in a CMOS implementation, if the size of the transistors at the input of the current mirror are W/L, the transistors sizes of the 1^{st}, 2^{nd}, . . . , 15^{th} output are W/L, 2W/L, . . . , 15W/L respectively, or

A current copier circuit capable of producing N−1 copies of the current unit Iu. This current copier can consists of a P-current mirror with N−1 outputs. Its input is connected to a current source Iu and each one of its outputs is connected to the input of a corresponding switch. N−1 switches that consist of an input, an output and a control input. Depending on the values of the control input either the switch is closed i.e., the input forms a short circuit with the output, otherwise the switch is open i.e., the impedance between the input and the output is too large (theoretically infinite). For example, in CMOS technology the switches can be implemented as pass gates using NMOS or PMOS transistors or both. The control input of each switch is connected to the corresponding output of a current comparator, the input of each switch is connected to the output of the said current copier of the current unit Iu and the output of each switch is connected to the output of the said DIVNxIu circuit.

A DIVNxIref circuit may be provided performing a quantization of an input current Iin to the closest lower multiple of a reference current Iref. DIVNxIref is a DIVNxIu circuit with Iu=Iref.

In some embodiments there may be provided a VDIVNxVu circuit performing integer division of an input voltage Vin with a reference voltage Vref. The voltage unit is Vu. The output of VDIVNxVu is a voltage nVu, where n is the highest positive integer with nVref≦Vin. This circuit can be used to perform the integer division or the floor function on a floating point voltage. VDIVNxIu may consist of N−1 differential or single ended voltage comparators, N−1 resistors and N−1 switches. The input Vin can be compared at each one of the N−1 voltage comparators with the reference voltages Vref, 2Vref, . . . , (N−1)Vref. The output of each voltage comparator controls a corresponding switch. The input of each switch is connected to a resistor. The other pin of all these resistors is connected to a common voltage Vcom. The outputs of the switches are connected together to one input of a differential amplifier with positive and negative feedback resistors. The other input of the differential amplifier is connected through another resistor to the common voltage Vcom. The value of the resistors connected to the switches are selected in such a way that the outputs of the differential amplifier are modified by the predetermined voltage Vu when an additional switch neighboring to the already closed switches is also closed.

A VDIVNxVref circuit may be provided performing a quantization of an input voltage Vin to the closest lower multiple of a reference voltage Vref. VDIVNxVref is a VDIVNxVu circuit with Vu=Vref.

DIVNxIu can be used as a function generator of the form:

$$Out = Iref {\sum }_{i = 1}^{m , {k}_{m + 1} Iref > In} {a}_{i}$$

In this case, the reference currents used by the comparators are k₁Iref, k₂Iref, . . . , k_{N-1}Iref and the current sources Iu are substituted by α₁Iref, α₂Iref, . . . , α_{N-1}Iref. For example, in the case that CMOS technology is used, the transistor sizes in the current copier-and-multiplier of the Iref and the current copier of Iref are selected as follows: if the size of the input PMOS transistors of the Iref current copier is W/L, then the sizes of the PMOS transistors at the N−1 outputs, are a₀W/L, a₁W/L, . . . , a_{N-1}W/L. If the size of the input PMOS transistor of the current copier-and-multiplier of Iref is W/L then the sizes of the PMOS transistors at the N−1 outputs are k₀W/L, k₁W/L, . . . , k_{N-l W/L, k}₀<k₁<, . . . , k_{N-1}. This function generation be implemented by a voltage mode divider circuit if the resistor values are appropriately selected. These resistor values depend on the characteristics of the differential amplifier that they are connected to through the switches.

A DIVNxIref circuit can be substituted with the components DIVN₁xIref1 and DIVN₂xIref2 if N=N₁N₂. If the upper limit of the input current range is Imax, then Iref1=Imax/N₁ and Iref2=Imax/(N₁N₂). The input of DIVN₁xIref1 is the input of the substituted DIVNxIref device. A copy of DIVN₁xIref1 output is subtracted from a copy of its input and the difference forms the input of the DIVN₂xIref2 component. The output of the DIVN₂xIref2 and a copy of the DIVN₁xIref1 output are added to form the output of the substituted DIVNxIref device. If q=Iin/N, then the overall output has the form: q·Iref2. The DIVN₁xIref1 and DIVN₂xIref2 components could be in turn recursively substituted with simpler division circuits just as described above. A large voltage mode divider VDIVNxVref can also be substituted by smaller ones in the same way using appropriate (more complicated) voltage adders/subtractors.

A DDIVNxIref circuit can be provided with two outputs performing an optimized quantization of an input current Iin to the closest lower multiple of a reference current Iref. This circuit is similar to the DIVNxIref but the current copier circuit and the switches described are duplicated. More specifically, a first current copier circuit capable of producing N−1 identical or modified copies of the reference current Iref consists of a P-current mirror with N−1 outputs. Its input is connected to an input reference current Iref and each one of its outputs is connected to the input of a corresponding switch that belongs to the first set of switches. The control input of each switch of the first set of switches is connected to the corresponding output of a current comparator. The input of each switch of the first set is connected to the output of the said first current copier of reference current Iref and the output of each switch is connected to the first output of the said DDIVNxIref circuit. The second current copier circuit capable of producing N−1 identical or modified copies of the reference current Iref consists of a P-current mirror with N−1 outputs. Its input is connected to an input reference current Iref and each one of its outputs is connected to the input of a corresponding switch that belongs to the second set of switches. The control input of each switch in the second set of switches is connected to the corresponding output of a current comparator. The input of each switch in the second set is connected to the output of the said second current copier of reference current Iref and the output of each switch is connected to the second output of the said DDIVNxIref circuit.

A 2-bit Current ADC circuit can be provided comprising a said DIV2xIref or DDIV2xIref circuit. The reference input of the said DIV2xIref or DDIV2xIref component is connected to the current source Iref, while its main input is driven by the input current. The output current of the said DIV2xIref component or the first output of the said DDIV2xIref component is input to a current comparator that compares it with Iref/2 and the comparator voltage output forms the most significant digit of the said 2-bit ADC. The output current of the said DIV2xIref component or the second output of the said DDIV2xIref component is subtracted from the input current and the difference is input to a current comparator that compares it with Iref/2. The voltage output of the current comparator is the least significant digit of the said 2-bit ADC. The input current is in the range 0 to 2Iref. If the said 2-bit ADC is not used at the output stage of an ADC with higher resolution but at the intermediate stages instead, the current comparators are omitted and its outputs are the output of the DIV2xIref component (or the said first output of the DDIV2xIref component) and the output of the current subtractor.

A 2ⁿ2^{m}-bit Current ADC can be provided comprising of multiple said 2-bit ADCs. The input of the root said 2-bit ADC is connected to the input current signal. The outputs of the said root 2-bit ADC are connected to a 2ⁿ-bit ADC and a 2^{m}-bit ADC respectively. This is potentially achieved through current mirrors that perform range adaptation or simply invert the current direction. The said 2ⁿ-bit ADC recursively consists of a said 2-bit ADC that connects its outputs to two 2ⁿ⁻¹-bit ADCs, the root 2-bit ADC of each of these two 2ⁿ⁻¹-bit ADC connects is outputs to two 2ⁿ⁻²-bit ADCs and so on. Similarly, the said 2^{m}-bit ADC recursively consists of a said 2-bit ADC that connects its outputs to two 2^{m-1}-bit ADCs, the root 2-bit ADC of each of these two 2^{m-1}-bit ADC connects its outputs to two 2^{m-2}-bit ADCs and so on.

In a similar way voltage mode dividers can be connected in a voltage mode ADC with binary tree structure. Alternatively the quotient and the residue of a single voltage mode divider can be connected to a pair of ADCs that are based on different architecture. For example, the voltage mode divider can drive the input of Flash ADCs. This connection to ADCs with different architecture such as Flash ADCs can also be done with current mode dividers, however, the combination is found to be more advantageous for voltage mode. In the voltage mode it removes any need for current to voltage converters in order to connect to fast voltage mode Flash ADCs.

A dual Sample and Hold circuit can be provided followed by a voltage to current converter (V2I) with offset correction that is capable of providing an input current required for current mode ADCs. The dual Sample and Hold circuit may consist of a first and a second Sample and Hold circuits. Each one of the first and the second Sample and Hold circuits can consist of a switch A and a switch B. The input of the switch A is connected to the positive pole of the input voltage. The output of the switch A is connected to the first pin of a small capacitor. The second pin of the capacitor is connected to the negative pole of the input voltage. The output of the switch A is also connected to the input of the switch B. The output of the switch B of the first Sample and Hold is the output of the dual Sample and Hold circuit. The output of the switch B of the second Sample and Hold is also connected to the output of the dual Sample and Hold circuit. The switch A of the first Sample and Hold and the switch B of the second Sample and Hold are activated with the High level of the Sample and Hold clock. The switch B of the first Sample and Hold and the switch A of the second Sample and Hold are activated with the Low level of the input clock. The dual Sample and Hold output and the negative pole of the input voltage can be connected to the base of two identical NMOS transistors of the V2I circuit. The sources of these transistors are connected to a current source Ibias. The drains of the NMOS transistors are connected to the drain of a PMOS transistor with W/L size and to the drain of a PMOS transistor with 2W/L size respectively. The gate of the W/L sized transistor is connected to its drain. The gate of the 2W/L sized transistor is connected to its drain and to the gate of a third PMOS transistor with size W/L. The sources of all PMOS transistors are connected to the power supply of the V2I. The drain of the third W/L PMOS transistor can be connected to a current source that removes the offset in order to have the output current starting from 0 uA. A NMOS transistor in CMOS technology or an NPN transistor in bipolar technology can be used for the implementation of the offset correction. The gate of the offset correction transistor is connected to an appropriate bias voltage and its source is connected to the ground. The drain of the offset correction transistor is connected to the input of an N-current mirror. The output of this current mirror is the output current of the V2I circuit.

For the achievement of at least one object mentioned above, a binary tree structure is provided. For example, in some embodiments if a conversion with 8-bit resolution is required, two analog values might be derived representing the 4 most significant and the 4 least significant bits respectively. Each one of these two 4-bit analog values is further split into two other analog values which produce the 2 most significant and the 2 least significant bits of the 4-bits analog value. Finally, the last four analog values are further split into totally eight analog values that provide the output of the 8-bit ADC after they are compared to a proper threshold value. The procedure described above can be represented by a binary tree like the one shown in FIG. 2. The binary tree describing an ADC implementation does not necessarily have to be balanced. For example, a 12-bit ADC can be implemented by a root level and two sub-trees corresponding to a 4-bit ADC (a 2 level binary tree) and an 8-bit ADC (a 3 level binary tree) as shown in FIG. 5a.

The binary trees mentioned in the previous paragraph may consist of nodes that are implemented by circuits of identical architectures. This architecture implements the integer division of the input analog value with a proper power of 2 in order to get an output analog value corresponding to the most significant bits. The input and output analog values are represented by electrical current intensity or electrical voltage. The output analog value produced by the integer division is multiplied by the same power of 2 that was used for the division and the result is subtracted from the input analog value. The resulting difference is used to produce the least significant bits (FIG. 1).

The integer division may be implemented by what is called a DIVNxIu,or a DIVNxIref or the DDIVNxIref or a VDIVNxVu,or a VDIVNxVref component. Iref is a reference current and Iu is the current unit, Vref is a reference voltage and Vu is the voltage unit. The DIVNxIu component accepts as input a current Iin and returns an output current nIu, where n is the highest positive integer with nIref≦Iin The integer division circuits used in current mode implementations are the DIVNxIref or DDIVNxIref components rather than the DIVNxIu one, since the first two components use a single current reference (Iref) instead of two (Iref and Iu) and they furthermore incorporate the necessary multiplication by the appropriate power of 2 that follows the division by the same power of 2 as shown in FIG. 1. The DIVNxIref and DDIVNxIref components accept as input a current Iin and return an output current or a pair of output currents respectively, that are the higher integer multiples of Iref with value less than or equal to Iin. In this way the DIVNxIref or DDIVNxIref module implements both the integer division with 2^{x} and the consequent multiplication with 2^{x} that was described in the last paragraph. The DIVNxIref or DDIVNxIref circuit can be implemented by a number of current comparators, if N is small or by simpler DIVNxIref or DDIVNxIref circuits for higher N values. In the first case, N−1 comparators are required, each one comparing a copy of the input current with Iref, 2Iref, 3Iref, . . . , (N−1)Iref references. Each one of these comparators controls a switch that allows an Iref current to pass through. The Iref currents that were allowed to pass through the switches are summed up in order to produce the multiple of the Iref current. If N is too high then two or more smaller sized DIVNxIref or DDIVNxIref circuits could be connected in series since the division by N can be implemented with two successive divisions by N1 and N2 where N=N1·N2 In this case, if N1, N2 are selected so that N1, N2<<N, the number of the required comparators is quite smaller with the cost of an extra delay since there are two instead of one levels of division. The VDIVNxVu component accepts as input a voltage Vin and returns an output voltage nVu, where n is the highest positive integer with nVref≦Vin. Vu can be selected equal to Vref. The integer division circuits used in voltage mode implementations are the VDIVNxVref

Current mirrors can be used to provide the copies of the input current and can be used to provide the multiples of the Iref that are used as references by the comparators of the DIVNxIref circuit. In N-current mirrors all the input and output currents flow into the mirror. The N-current mirrors can be implemented for example with NMOS transistors in the case the CMOS technology is used or NPN transistors in the case the bipolar technology is employed. In P-current mirrors all the input and output currents flow out of the mirror. The P-current mirrors can be implemented for example with PMOS transistors in CMOS technology or PNP transistors in bipolar technology. The subtraction of the DIVNxIref circuit output or of the one output of the DDIVNxIref circuit from the initial current is performed by connecting the outputs of an N-current mirror and a P-current mirror that reproduce the corresponding currents. The difference between the current that is sunk by the N-current mirror and the one that the P-current mirror tries to supply, is driven in a load that can be the input of an N-current mirror. The sizes of the transistors of these mirrors should be carefully selected in order to achieve an accurate current subtraction that is immune to the mismatch effect. The existence of two different outputs in DDIVNxIref allows for the optimization of the values that will be subtracted from the input current as well as the corresponding values that will be used as the main output of the divider by the following stages.

The input current of the ADC circuit can be supplied by a Sample and Hold (S/H) circuit and/or use a linear Voltage to Current converter (V2I) since the ADC circuits are usually sampling voltage levels instead of current ones. A S/H+V2I circuit disclosed consists of a pair of S/H circuits that are activated at different levels of the sampling clock. The outputs of this S/H pair are connected to a linear V2I circuit. The outputs of the usual V2I circuits are linear within a current region which is not suitable for the input of the ADCs that are disclosed in the present invention. For this reason, a current offset correction is applied to the output of the V2I circuit, which may be provided by the specific (S/H+V2I) circuit disclosed in this invention.

### BRIEF DESCRIPTION OF THE DRAWINGS

Embodiments of the present invention will be described according to the appended drawings in which:

FIG. 1a illustrates the current mode module that implements the integer division and outputs the quotient and the residue of the division;

FIG. 1b illustrates the voltage mode module that implements the integer division and outputs the quotient and the residue of the division;

FIG. 2 describes how a binary tree structure consisting of blocks like the one presented in FIG. 1a and 1b, can be used to implement an n-bit ADC. This drawing includes the description of smaller ADCs with 4 or 2-bit resolution;

FIG. 3 shows a 16-bit current mode ADC. The root of a 16-bit ADC tree is described and its 8-bit current mode ADC sub-trees are represented as blocks;

FIG. 4a shows how a DIVNxIref device can be substituted by two smaller dividers DIVN₁xIref1 and DIVN₂xIref2 with N=N₁N₂;

FIG. 4b shows how a VDIVNxVref device can be substituted by two smaller dividers VDIVN₁xVref1 and DIVN₂xVref2 with N=N₁N₂;

FIG. 5a shows the root of a 12-bit non-balanced current mode ADC tree;

FIG. 5b shows the root of a 10-bit non-balanced voltage mode ADC tree;

FIG. 6a shows the general structure of a DIVNxIref or DIVNxIu device;

FIG. 6b shows the general structure of a DDIVNxIref device;

FIG. 6c shows the general structure of a VDIVNxVref device;

FIG. 7 shows a DIV2xIref circuit;

FIG. 8 shows a DIV4xIref circuit with internal current mirrors used as current copiers and multipliers of the reference current Iref;

FIG. 9 shows a DIV16Iref circuit with internal current mirrors used as current copiers and multipliers of Iref;

FIG. 10a shows the plot of the output current of a DIV16x8 uA circuit where the input current is ranging between 0 and 140 uA;

FIG. 10b shows the plot of the output of differential VDIV16x650 uV circuit;

FIG. 11 shows a 2-bit current mode ADC comprising a DIV12xIref circuit like the one presented in FIG. 7, various current mirrors for current copying and for the implementation of the current subtraction and an external current comparator;

FIG. 12 shows a 4-bit current mode ADC circuit consisting of one DIV4xIref (FIG. 8), two 2-bit current mode ADCs (FIG. 11), and various current mirrors for current copying and for the implementation of the current subtraction;

FIG. 13 shows an 8-bit current mode ADC circuit consisting of one DIV16xIref (FIG. 9), two 4bit current mode ADCs (FIG. 12), and various current mirrors for current copying and for the implementation of the current subtraction;

FIG. 14 shows the dual Sample and Hold and the V2I circuit with offset correction;

FIG. 15 shows the output of the V2I circuit;

FIG. 16 shows the outputs of the 8-bit current mode ADC that was designed as case study, where the input current ranges from 0 to 140 uA; and

FIG. 17 shows the DNL and INL error of the 8-bit current mode ADC that was designed as case study;

FIG. 18 shows an 8-bit voltage mode ADC circuit that consists of a VDIV16x Vref (FIG. 6c), a thermometer to binary code encoder and a 4-bit Flash ADC; and

FIG. 19 shows the outputs of an 8-bit voltage mode ADC.

### PREFERRED EMBODIMENTS OF THE PRESENT INVENTION

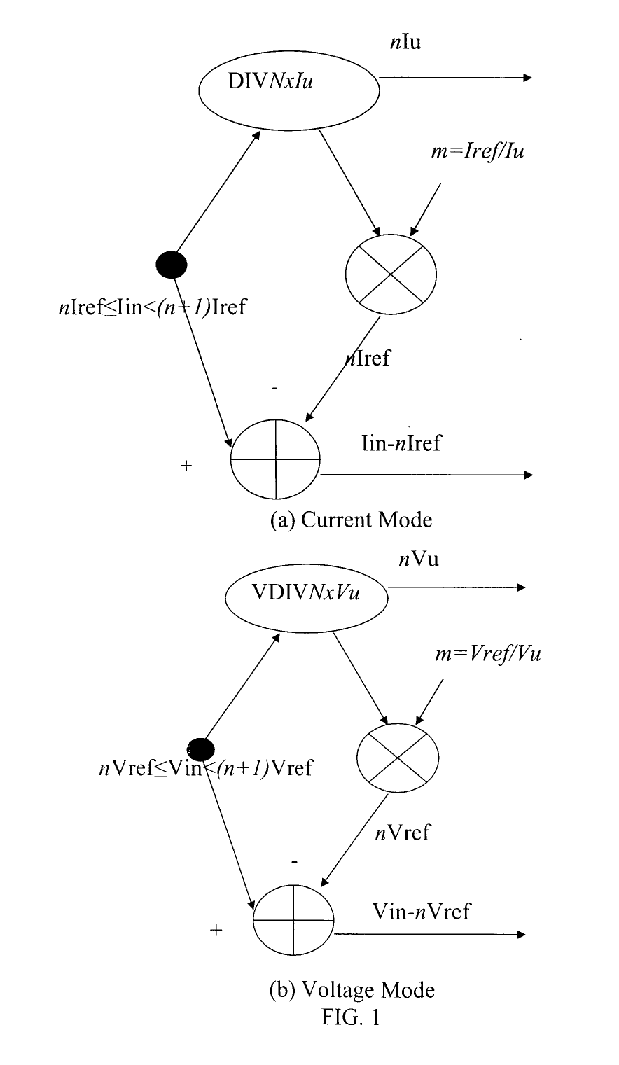

The basic building block of the Analog-to-Digital Converters disclosed in the present invention is the module described in FIG. 1. The current mode integer divider DIVNxIu accepts as input a current Iin and uses a reference current Iref and the current unit Iu. If nIref<Iin<(n+1)Iref, then the output of DIVNxIu is nIu. Therefore n corresponds to the quotient of the division Iin/Iref. A copy of the output of the DIVNxIu component is multiplied by the constant m=Iref/Iu and subtracted from the input current Iin in order to produce the residue of the division. If Iu is replaced by Iref (not necessarily equal to the current unit), the component will be called DIVNxIref. The multiplication by m described in FIG. 1a is incorporated into the DIVNxIref component in this case. DIVNxIref uses a single current reference (Iref) instead of two (Iref and Iu) that are used by DIVNxIu. If the pure division quotient is needed, the output of the DIVNxIref component has to be divided by the constant m. For simplicity reasons, we mostly describe the use of DIVNxIref components in the present invention.

In a similar way the component VDIVNxVu is defined in voltage mode for the implementation of integer division as shown in FIG. 1b. The component VDIVNxVu accepts as input the voltage Vin and uses a reference voltage Vref and the voltage unit Iu. If nVref≦Vin<(n+1)Vref, then the output of VDIVNxVu is nVu. Therefore n corresponds to the quotient of the division Vin/Vref. The output of the VDIVNxVu component is multiplied by the constant m=Vref/Vu and subtracted from the input voltage Vin in order to produce the residue of the division.

$${\sum }_{i = 1}^{{log}_{2} n} \frac{n}{{2}^{i}}$$

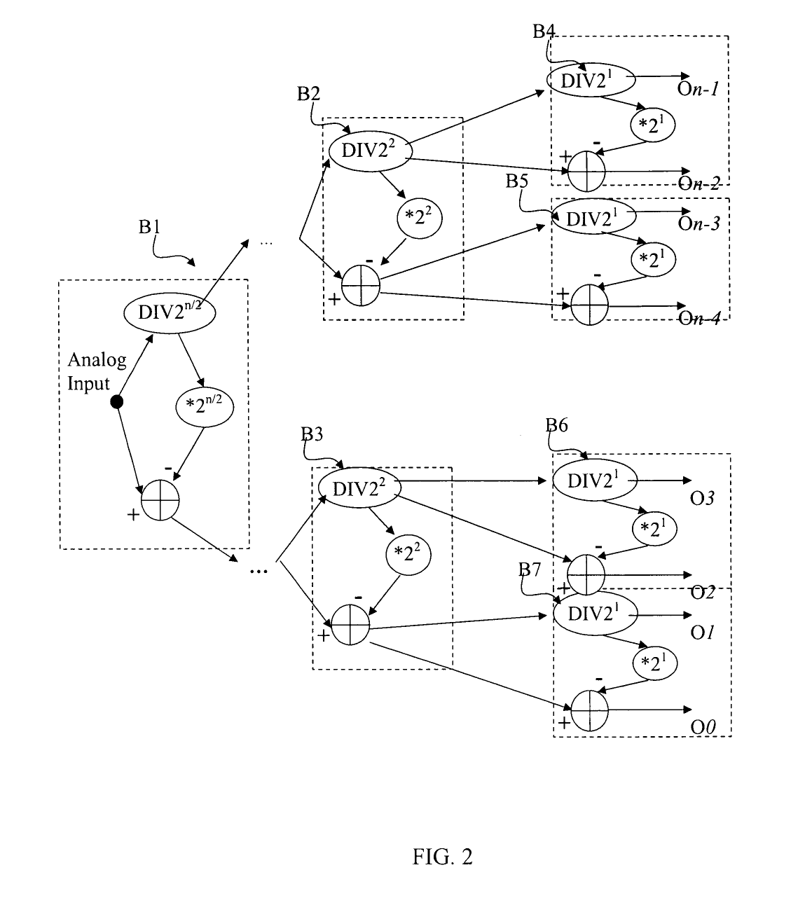

The general architecture of an n-bit ADC is presented in FIG. 2. It consists of elementary blocks, like the one described in FIGS. 1a and 1b. The visible blocks in FIG. 2 are named B1, B2, B3, B4, B5, B6 and B7 and are connected in a binary tree structure. Each one of these blocks consists of an integer divider, a multiplier and an adder. The input of each block is divided by a specific number of the form: 2^{x}. The integer quotient of the division is multiplied by 2^{x} and the result is subtracted from the initial block input in order to get the residue of the integer division. The residue and the integer quotient of the division are the two block outputs. Each one of these blocks is actually a 2-bit ADC if the outputs are mapped to 0 or 1 based on a comparison with a threshold value. If the outputs of a block are connected to another pair of blocks, a 4-bit ADC can be constructed. For example, the blocks B2, B4 and B5 form a 4-bit ADC and the blocks B3, B6 and B7 form another 4-bit ADC. The root of the n-bit ADC tree is the block B1 in FIG. 2 and its outputs are connected to the two (n−1)-bit ADCs.

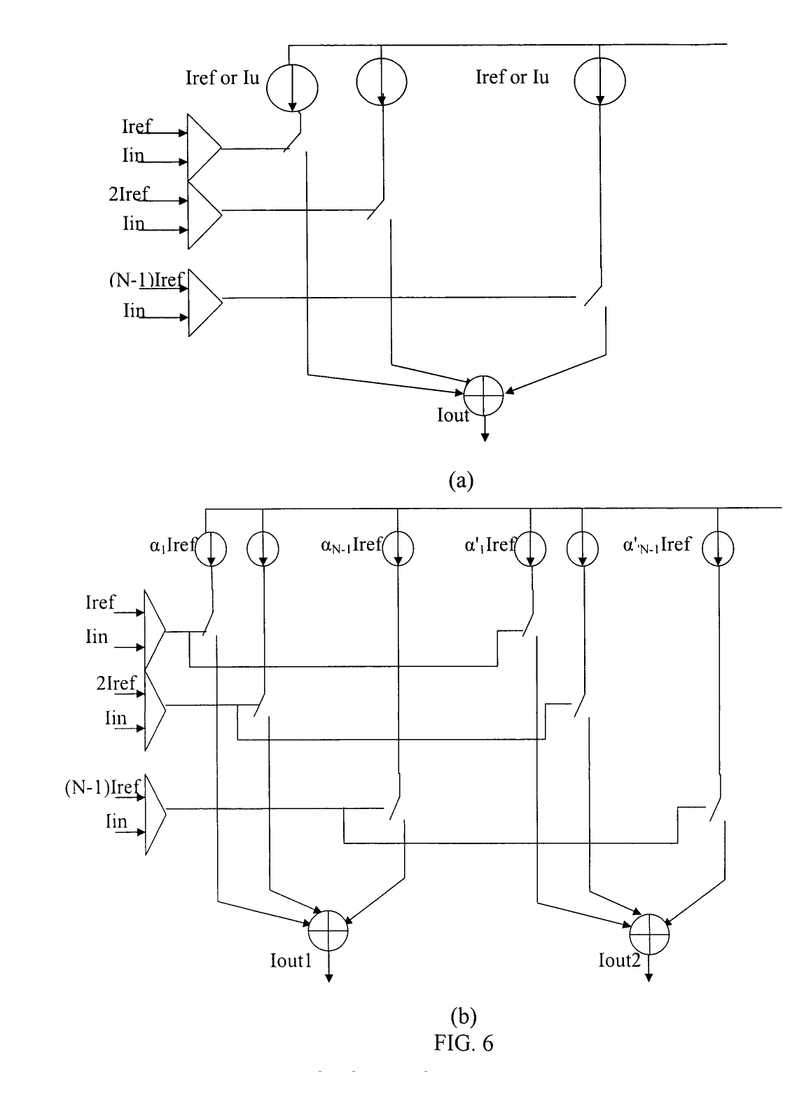

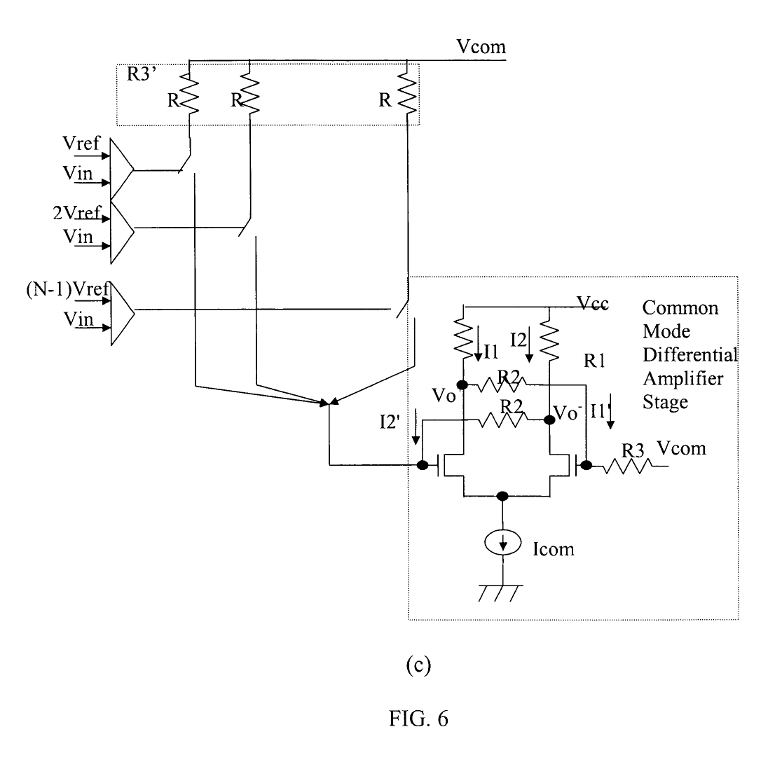

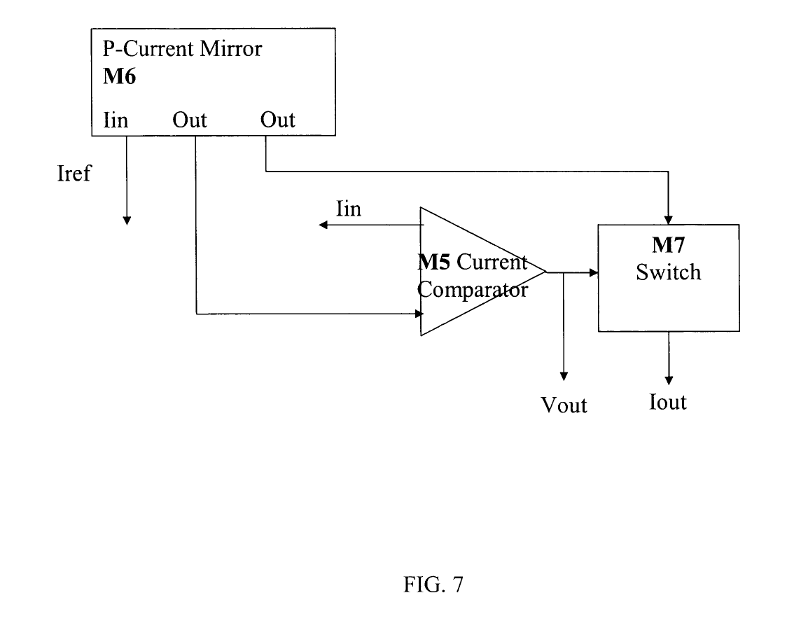

The integer divider (FIG. 6) used at each level of the binary tree (FIG. 2) implements a specific integer division that differs from level to level. The dividers at the leaf blocks B4, B5, B6 and B7 divide the input by 2. The dividers at the intermediate nodes, divide the input by 4 and the ones at the root level of the n-bit ADC, divide the input by 2^{n/2}. Generally, if the leaves of the tree are the level L=0 of the tree, we can state that a division by 2²^{^{L}} should be performed at the blocks of level L. For example, a 16-bit ADC can be constructed by using a root block that consists of a component that performs integer division by 256, the quotient of the division is multiplied by 256 and subtracted by the input number in order to get the remainder of the integer division. The outputs of the 16-bit ADC root block are connected to a pair of 8-bit ADCs. The input of the root block can be in the range [0 . . . 65536] (resolution step=1).However, if the resolution step is expressed in microamperes or microvolts, it is difficult to implement an ADC system with electronic components operating accurately at such a wide input range. For this reason, some range adaptation (e.g., division by a constant number) may be implemented to the input of a block.

If rather than (or in addition to) a conversion from analog to digital binary, a conversion from analog to multivalue/multilevel digital representation is required, the outputs of the intermediate nodes of the tree that is shown in FIG. 2 can be used. The outputs of Level 1 nodes are quaternary digits, the outputs of the Level 2 nodes are 16-value digits etc. Multivalue signals are sometimes used for inter or intra component communication in order to reduce wiring area and power consumption and therefore these outputs of the intermediary nodes of the tree can be very useful.

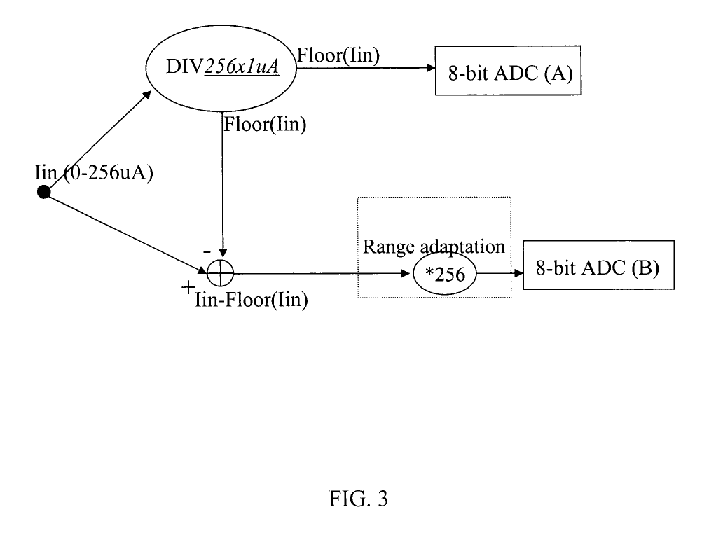

FIG. 3 shows how a 16-bit current mode ADC can be constructed using two 8-bit current mode ADCs operating in the range [0 . . . 256 uA] (resolution step=1 uA) and a root block operating at the same input range. Since this is a 16-bit ADC the conversion step is 256/2¹⁶=3.90625 nA. The integer divider DIV256x1 uA in effect implements a “floor” function by providing only the integer part of the input current intensity that is expressed in microamperes. This integer divider output is then provided as the input of the 8-bit ADC (A) that generates the most significant bits. The DIV256x1 uA output is subtracted from the input current and the difference which is the floating point part of the overall input (<1 uA) is multiplied by 256 to adapt to the input range of the 8-bit ADC (B) in order to provide the least significant bits.

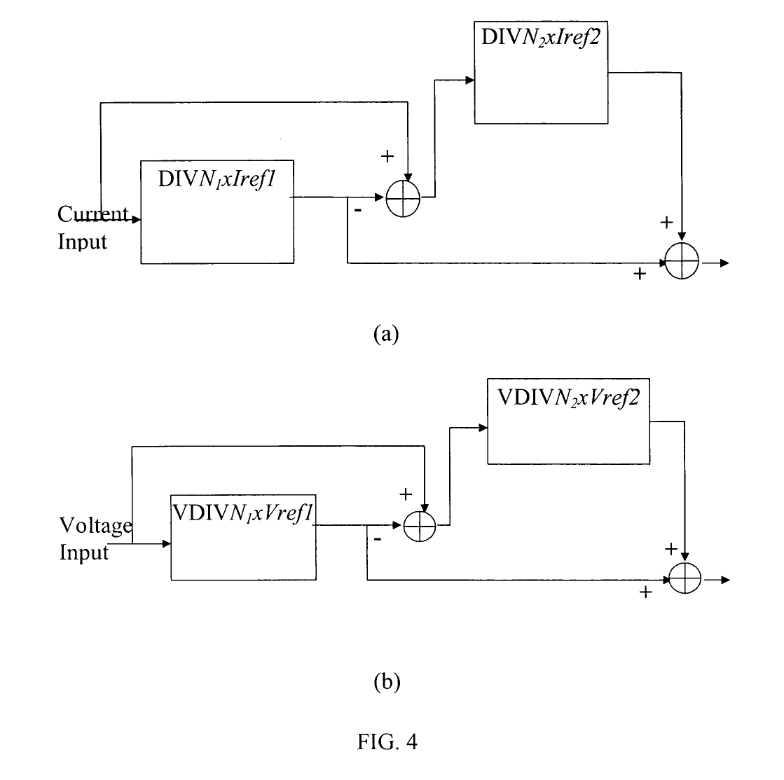

A DIVNxIref component requires N−1 current comparators and N−1 current sources. In order to reduce the required number of components, a DIVNxIref device can be replaced by two simpler ones: DIVN₁xIref1 and DIVN₂xIref2, as shown in FIG. 4a. The number N should be equal to N₁N₂, while the reference currents Iref1 and Iref2 are chosen as Imax/N₁ and Imax/(N₁N₂) respectively where Imax is the maximum value of Iin.

The output of the circuit shown in FIG. 4a produces the integer part of Iin/N multiplied by

$$Iref 2 ( = ⌊ \frac{{I}_{in}}{N} ⌋ \times Iref 2 ) .$$

Similarly, each one of the components DIVN₁xIref1 and DIVN₂xIref2 can be recursively substituted by simpler integer dividers. In this way, a DIVNxIref device can be implemented by several smaller components thus reducing significantly the overall number of required comparators and current sources. The cost of this solution is lower speed since it introduces more delay stages. For example, a DIV256x1 uA component using a straightforward implementation requires 256 current comparators and (256) 1 uA current sources. This number can be reduced to 32 comparators and current sources only, if the DIV256x1 uA block is substituted with a DIV16x16 uA and a DIV16x1 uA component connected as shown in FIG. 4a. This architecture is based on the equation: Input/256=(Input/16)/16. Since the goal in this example is to produce the integer part of a floating point value in the range [0 . . . 256 uA], a DIV16x16 uA block is initially used to round the input at the closer lower multiple of 16 uA. The output of the DIV16x16 uA component is subtracted from the input and their difference is a floating point value between 0 and 16 uA. This value is used as input to the DIV16x1 uA component which outputs the integer part of the floating point input. The integer output of the DIV16x1 uA is added up to the integer output of the DIV16x16 uA and the result is the integer part of the main input.

Large voltage mode integer dividers can also be substituted by simpler ones as shown in FIG. 4b. The output of this circuit is the integer part of Vin/N if Vref1 and Vref2 are chosen as Vmax/N₁ and Vmax/(N₁N₂). Nevertheless, the required additions and subtractions in this case are implemented differently and often in a more complicated way such as by using differential amplifiers.

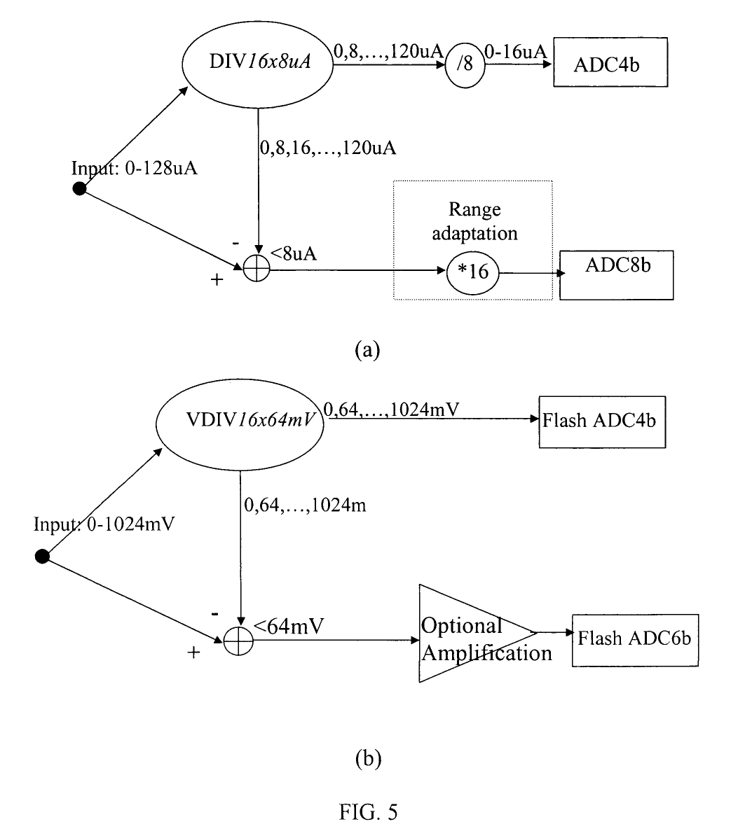

A non-balanced tree is used for the implementation of an n-bit ADC, if n is not power of 2. For example, the root block of a 12-bit current mode ADC is presented in FIG. 5a. The input current is assumed to be in the range [0 . . . 128 uA], thus the resolution is 31.25 nA. The input is rounded at the closer lower multiple of 8 uA by the DIV16x8 uA component. This multiple of 8 uA is divided by 8 and is used as input to a 4-bit ADC that operates in the range 0-16 uA. The outputs of the 4-bit ADC are the most significant bits of the 12-bit ADC. A copy of the output of the DIV16x8uA is also subtracted from a copy of the input and the difference is multiplied by 16 in order to adapt to the input range of an 8-bit ADC that operates in the range [0 . . . 128 uA]. The 8-bit ADC generates the 8 least significant bits of the overall 12-bit ADC. The proposed integer division circuits can also be used in conjunction with ADCs of different architecture like Flash ones, though for reasons described earlier this is of more use for the voltage mode option.

For example, in FIG. 5b, a 10-bit voltage mode ADC is implemented using a VDIV16x64 mV component at the input and a pair of Flash ADCs that are connected at the quotient and residue output of the VDIV16x64 mV component. Assuming that the input is 0 to 1024 mV, the quotient of the division of the input by 16 can take the values: 0, 64 mV, 128 mV, . . . , 1024 mV and the residue can take the values 0 . . . 63 mV. The 4-bit Flash ADC connected to the quotient has a conversion step of 64 mV while the 6-bit Flash ADC connected to the residue has a conversion step of 1 mV. If this is too small the residue value can be amplified before entering the 6-bit Flash ADC that generates the least significant bits.

The general structure of a DIVNxIref or a DIVNxIu device is shown in FIG. 6a. N−1 current comparators compare the input current with the reference currents Iref, 2Iref, . . . , (N−1)Iref. The ouput of each current comparator controls a switch. If a switch is closed, a reference current Iref or the current unit Iu passes through and all the reference currents passing through the closed switches are added up at the output of the DIVNxIref or the DIVNxIu device respectively. The copies of the input current, the reference currents and the multiples of the reference current are produced by current mirrors. In the following, we use DIVNxIref rather than DIVNxIu since the former component uses a single reference current (Iref) instead of two (Iref and Iu) and incorporates the necessary multiplication by the power of 2 that follows the division by the same power of 2 performed in each node of the tree presented in FIG. 2. The output of the DIVNxIref circuit used at the root of any n-bit ADC subtree is duplicated by current mirroring. One of the output current copies is used to generate the n/2 most significant bits of the specific ADC and the second output current copy is subtracted from the DIVNxIref input. The outcome of the subtraction is used to generate the n/2 least significant bits of the specific ADC. The n/2 least or most significant bits are generated by (n−1)-bit ADC subtrees. The two DIVNxIref output current copies may be optimized in order to handle more efficiently the effect of transistors' mismatch and to improve linearity. This is achieved by modifying appropriately the levels of each output that correspond to a specific division outcome and are determined by simulation or experimental results. This type of optimization may be advantageous especially at the root nodes of the binary tree that implements a high resolution ADC and can be performed by an alternative version of DIVNxIref circuit that is called DDIVNxIref.

A DDIVNxIref is shown in FIG. 6b and is realized by duplicating the current copier circuits and the switches used in the DIVNxIref block and produces two outputs corresponding to the two sets of current sources. The values of the corresponding current sources in the two sets may be equal to Iref or they may differ slightly if the simulation tests indicate that the linearity and the transistor mismatch effect will be improved in this way. For example, the DDIVNxIref output that will be subtracted from the input of the DDIVNxIref in order to produce the residue that represents the least significant bits may need to be an exact multiple of Iref to ensure better linearity, while the DDIVNxIref output that represents the most significant bits and is connected directly to an ADC subtree may need to have levels that are not exact multiples of Iref in order to achieve higher mismatch immunity. For example, the output that will be subtracted from the input current may need to be exactly: 0, Iref, 2Iref, . . . , or NIref while the output that will drive the most significant bits ADC may need to be: 0, 1.5Iref, 2.5Iref, etc. In this case, all the current references that produce the first output will be exactly Iref, while the current sources that will be used to produce the second output will all be Iref except for the first current source that will be 1.5Iref. Moreover, if the outputs of a DDIVNx(Iref/2)component are connected together, the resulting component is equivalent to a DIVNxIref block. Such an interconnection offers higher mismatch immunity due to the redundancy introduced by the double current sources.

In the following current mode examples it will be considered that DIVNxIref devices are used for reasons of simplicity although they can be equivalently replaced by DDIVNxIref devices as discussed previously.

In voltage mode implementations of the ADC tree of FIG. 2 the VDIVNxVu integer divider shown in FIG. 6c can be used. The input Vin is compared to Vref, 2Vref, . . . , (N−1)Vref. The thermometer (unary) code of the voltage mode comparator outputs controls how many resistors R will be connected in parallel to form the total resistance R3′. Common mode voltage Vcom is connected to the inputs of a differential amplifier through R3 and R3′. By modifying the total resistance R3′, the differential output ΔV=Vo⁺−Vo⁻ can have values that are multiples of the unit voltage Vu. The individual resistors that can be dynamically connected in parallel to form the appropriate R3′ values are determined by the following equations:

Icom=I1−I1′+I2−I2′

Vcc−I1R1−I1′(R2+R3)=Vcom

Vcc−I2R1−I2′(R2+R3′)=Vcom

ΔV=Vo⁺−Vo⁻=Vcc−I1R1−(Vcc−I2R1)=I2R1−I1R1

A DIV2xIref circuit consisting of a single current comparator (M5) is presented in FIG. 7. The output of this comparator is connected to the switch M7. If the input current Iin is higher than the reference current Iref the comparator output is high and M7 is on, enabling the current Iref to pass through M7 and reach the output. In this case Iout=Iref and Vout=Vcc, otherwise Iout=0 and Vout=0.

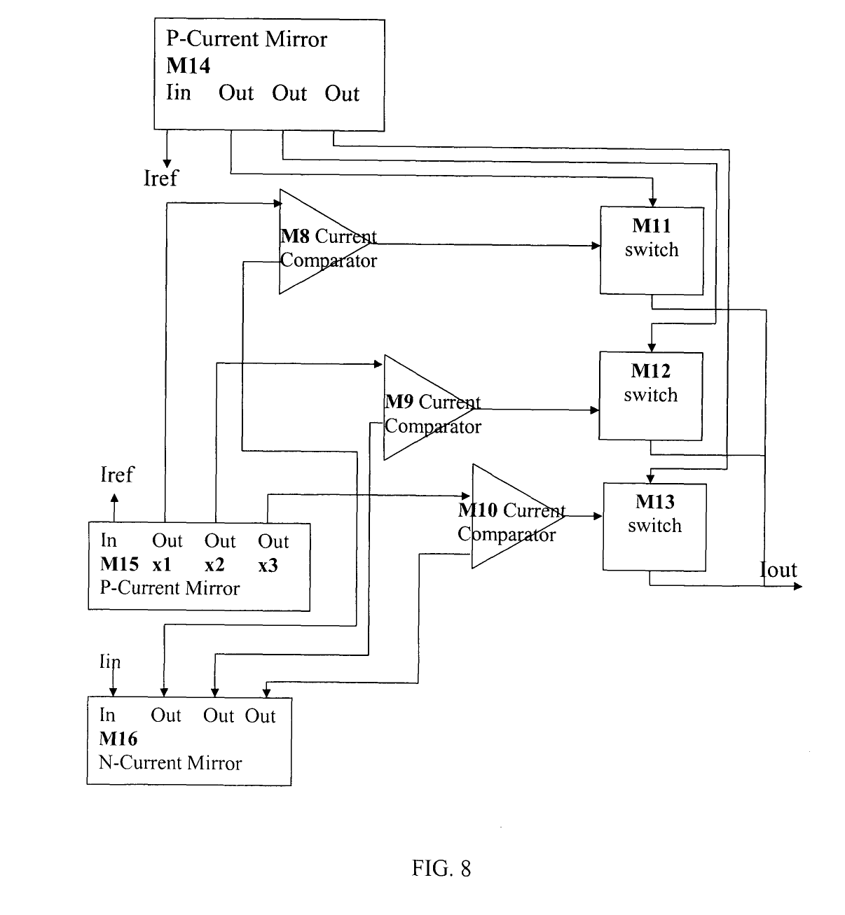

An implementation of a DIV4xIref circuit is shown in FIG. 8. The input is in the range [0 . . . 4Iref) and the output is one of the values 0, Iref, 2Iref, 3Iref. The P-current mirror M15 produces the currents Iref, 2Iref and 3Iref at its outputs. In the case that for example, M15 is implemented in CMOS technology, the PMOS transistors of M15 should have the same Length (the smallest possible) but their Widths (W) will be different: if the transistors at the input of the mirror have size W/L, then the transistors at the outputs x1, x2, x3 should have sizes W/L, 2W/L and 3W/L respectively. The currents Iref, 2Iref and 3Iref are the reference values used by the three current comparators M8-M10. The N-current mirror M16 acts as a current copier of the input Iin and feeds the rest inputs of the current comparators. The output of the comparators M8, M9 and M10 is a thermometer code i.e., can have one of the values 000, 100, 110 or 111. These outputs control the switches M11, M12 and M13. The current that is allowed to flow through those switches is determined by the P-current mirror M14 that produces 3 copies of Iref. The output currents controlled by the switches M11-M13 are added up to form the output of this circuit.

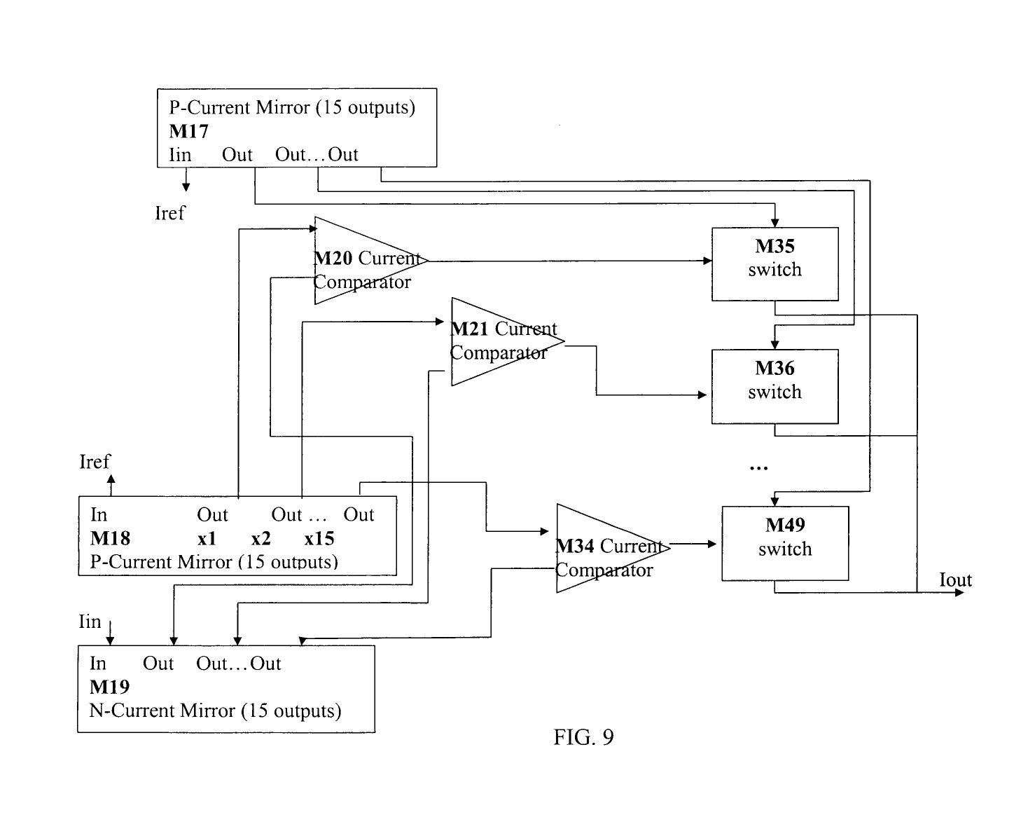

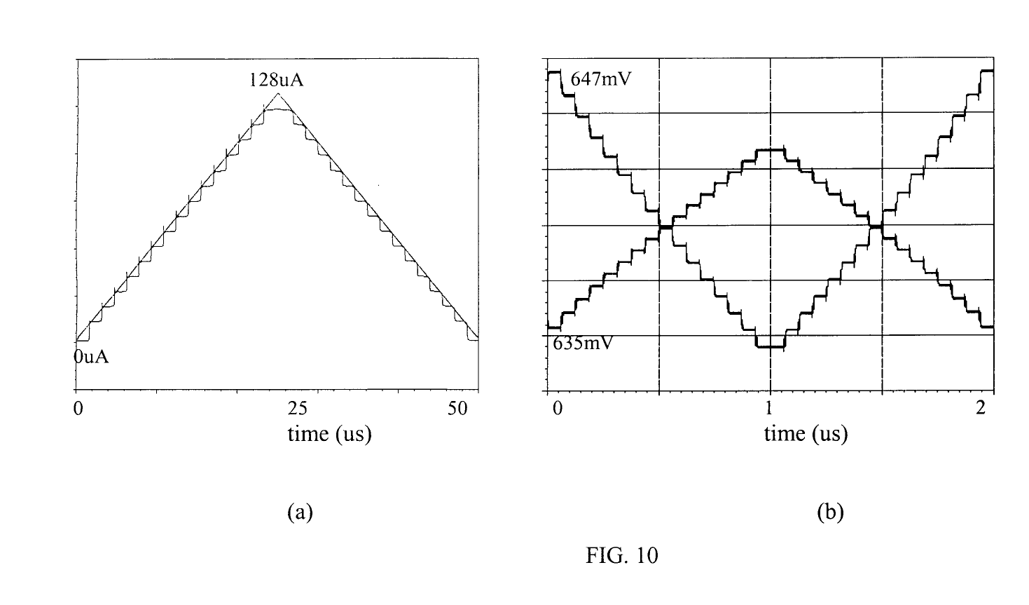

FIG. 9 presents an extension of FIG. 8 for the implementation of a DIV16xIref component that performs an integer division by 16. The DIV16xIref component was used in the development of the 8-bit ADC (the DIV16xIref lies in its root block) and consists of 15 current comparators M20-M34. The comparator reference currents Iref, 2Iref, . . . , 15Iref are provided by the P-current mirror M18 that has 15 outputs. In the case that for example, M18 is implemented in CMOS technology, the transistor sizes at the input of M18 have W/L size while the size of the transistors at the x1, x2, . . . , x15 outputs are W/L, 2W/L, . . . , 15W/L respectively. The 15 current sources of Iref are provided by the 15 outputs of the current mirror M17. The outputs of M17 are connected to the switches M35-M49. The input and the output of the DIV16x8 uA module in the case that the input current ranges between 0 and 140 uA is shown in FIG. 10a. The outputs of the voltage mode integer divider VDIV16x650 uV that is based on the circuit presented in FIG. 6c are shown in FIG. 10b.

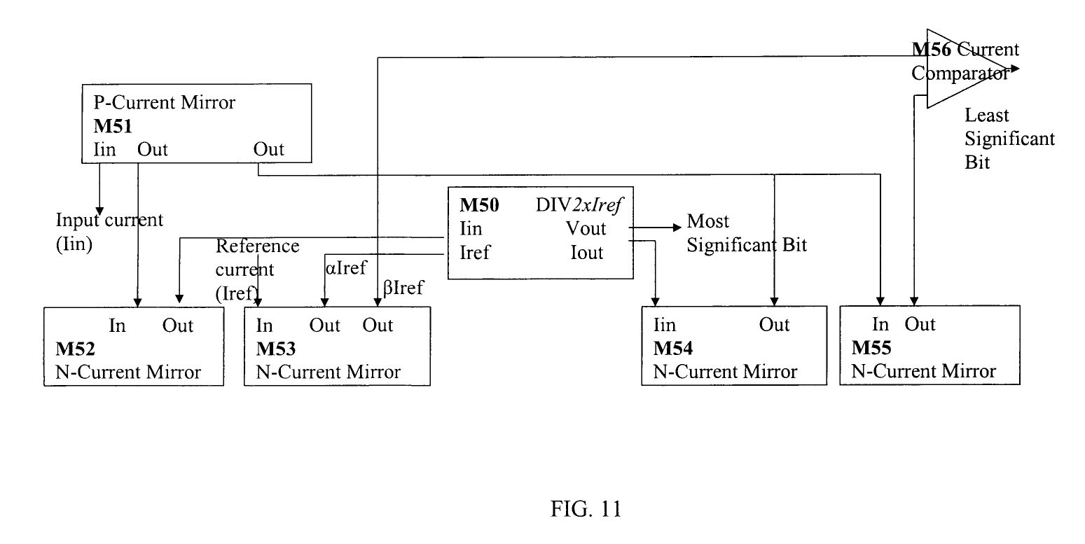

A 2-bit current mode ADC that works in the range [0,2Iref) is shown in FIG. 11. Two copies of the input current are generated by the 2-output P-current mirror M51. The N-current mirror M52 is used to change the direction of the input current. One copy of Iin is used directly as input to the DIV2xIref component M50 that was described in FIG. 7. The second input of DIV2xIref is biased to the reference current Iref provided by the N-current mirror M53 that produces two copies of Iref. The output of the DIV2xIref component (it can be one of the values: 0 or Iref) is mirrored in M54. The output of M54 is subtracted from one copy of the input current Iin that is mirrored in M51. The difference is in the range [0,Iref) and this difference is input to the mirror M55. The output of M55 is compared to a threshold (Iref/2 in our case) that is produced by the second output of the M53 current mirror. The comparison is performed by the current comparator M56. The outputs of the M53 current mirror may be optimized by using appropriate α and β. The output of the M56 comparator is the least significant bit while the voltage output of M50 is the most significant bit of the 2-bit ADC.

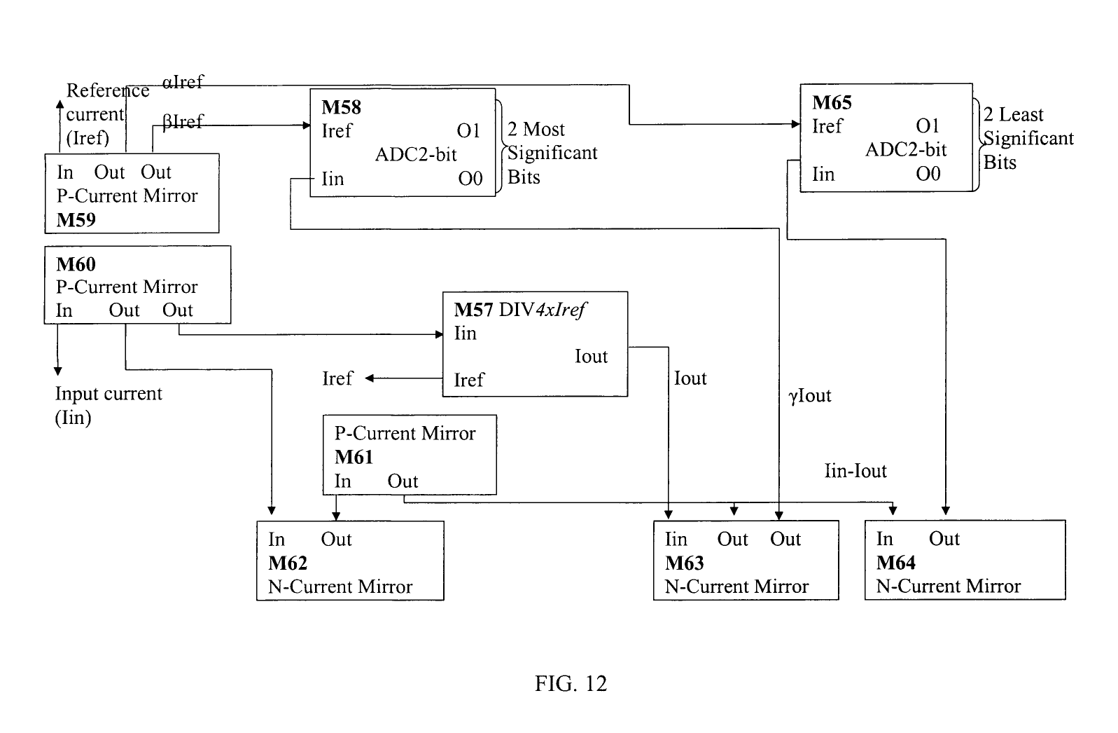

A 4-bit current mode ADC is shown in FIG. 12. The DIV4xIref divider M57 accepts as input a reference current Iref and a copy of the input current Iin. The P-current mirror M60 generates two copies of the input current Iin. The P-current mirror M59 generates two (optimized) copies of Iref. The input range of the 4-bit ADC is [0,4Iref) and the DIV4xIref output is 0, Iref, 2Iref or 3Iref. The output of the DIV4xIref is mirrored in M63 that generates two copies of the DIV4xIref output. One of the outputs is subtracted from the Iin output of M61 and the difference is mirrored at the output of the M64 N-current mirror. The output of M64 is connected to the input of the 2-bit current mode ADC M65 described in FIG. 11. The other copy of DIV4xIref output that is generated by the M63 current mirror (γlout) is the input to the other 2-bit ADC: M58. The input current range of the M58 and M65 current mode ADCs may be different and the necessary adaptation is performed by choosing appropriate α, β and γ. The current mirrors used in FIG. 12 are subject to optimization in order to achieve the appropriate range adaptation. The 2 most and the 2 least significant bits of the 4-bit ADC are the outputs of M58 and M65 respectively.

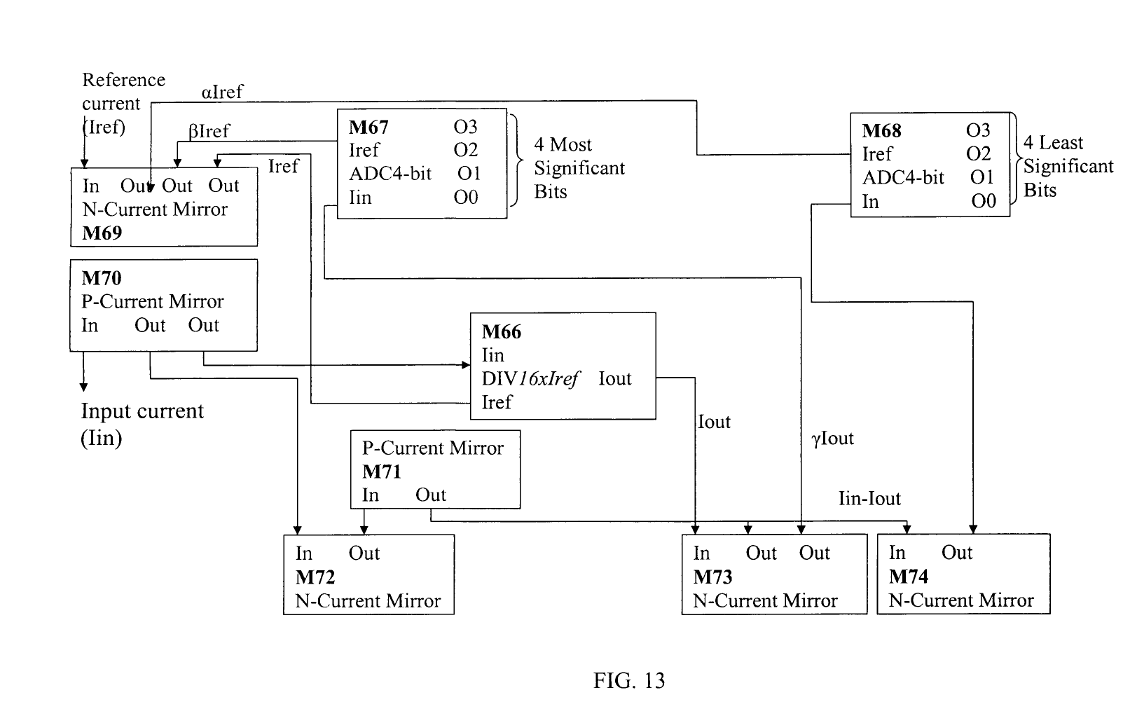

An 8-bit current mode ADC can be implemented as shown in FIG. 13. A DIV16xIref integer divider is used in this case and two current mode 4-bit ADCs (like the ones in FIG. 12) are connected at its outputs. Note that the copy of the main input current that will be used for the subtraction form the DIV16xIref output is passing through the N- and P-current mirrors M71 and M72 in order to compensate the delay introduced by DIV16xIref.

Current mode ADCs with different sizes like 12-bit and 16-bit can be designed based on the architectures presented in FIGS. 3, 4a and FIG. 5a. The various current multiplication and division operations can be achieved by the use of current mirrors with transistors that are appropriately sized. The current mirrors are also used to adapt the current direction when the various blocks are interconnected.

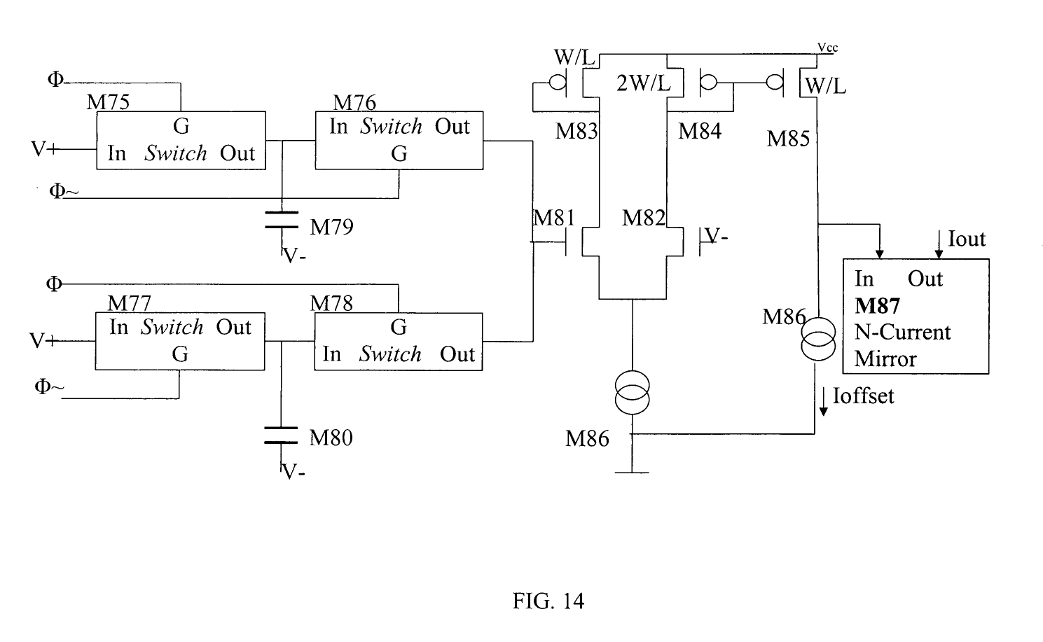

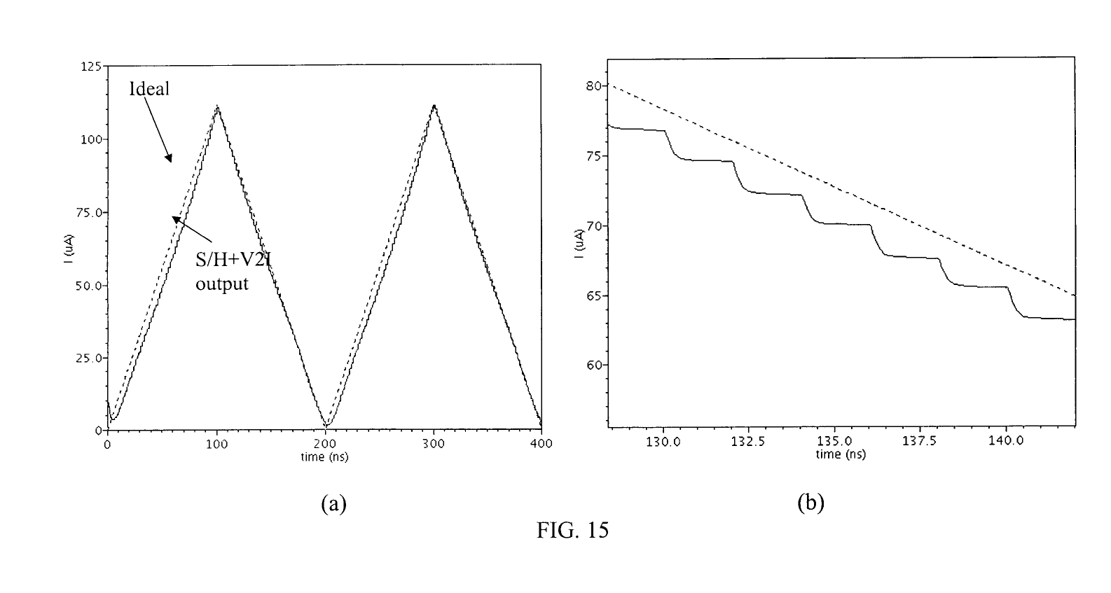

Since an ADC is usually sampling voltage rather than current, a Voltage to Current (V2I) converter circuit can be used at the input of a current mode ADC. Moreover, a Sample and Hold (S/H) circuit should also be used in order to keep the input stable for the period that is needed by the ADC outputs to be settled. A proper combination of S/H and V2I circuit is disclosed in FIG. 14. The input voltage is applied at V+ and V−. V+ is connected to the input of a S/H pair. Each one of the S/H circuits in the pair consist of two switches (M75/M76 and M77/M78) that can be implemented for example as NMOS or PMOS switch transistors or CMOS pass gates in the case that CMOS technology is employed. If the sampling clock Φ is high then M75 and M78 switches are on. In this way, M79 is charged but it is isolated from M81 since M76 is off. The stored voltage of M80 is applied to the gate of M81 through the M78 switch that is on. The gate of M82 is connected to the negative pole of the input voltage. When the sampling clock Φ is low, the stored voltage of M79 is applied to the gate of M81 while M80 is charged by the input since M76 and M77 switches are on. Using this “ping pong” structure the sampling rate is double the sampling clock frequency. The transistors M81-M85 along with the current source M86 form a V2I circuit. Nevertheless, the linear operating range of this V2I does not start from 0 uA i.e., there is an offset. The current source M86, (which can be implemented by using a properly biased transistor), draws the offset current and thus achieves linear operation in a range that starts from 0 uA. FIG. 15a shows the output of the V2I circuit in the case that the input of the S/H ranges between 0 and 0.8V. A shorter input range is used in FIG. 15b in order to observe the S/H steps.

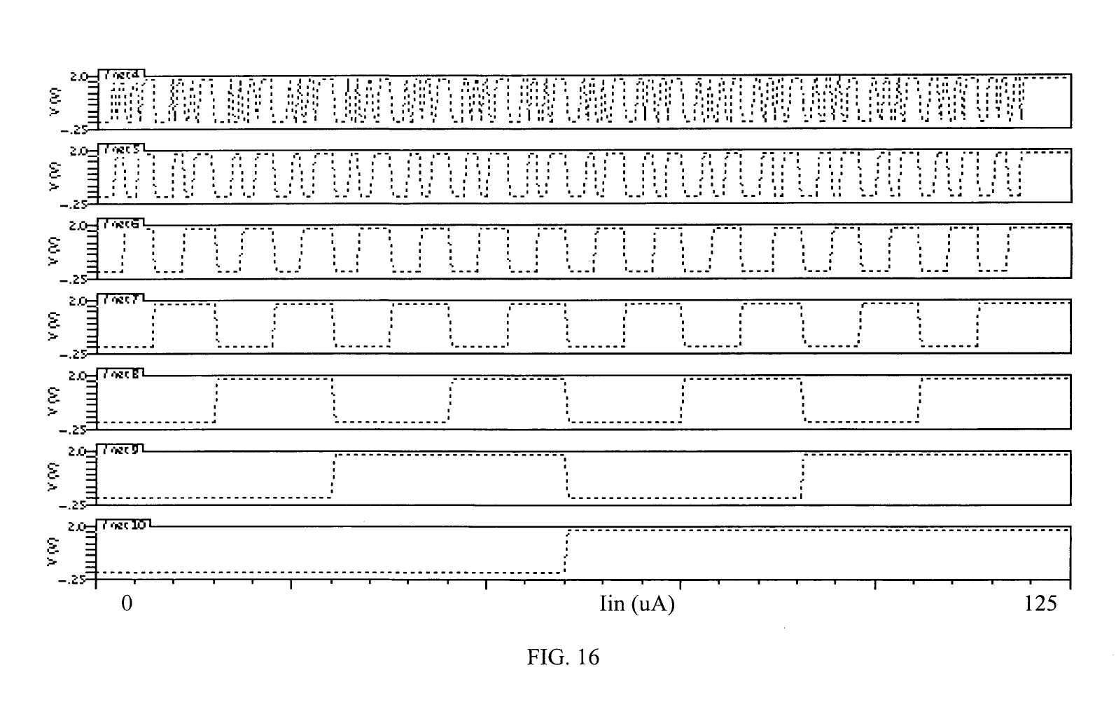

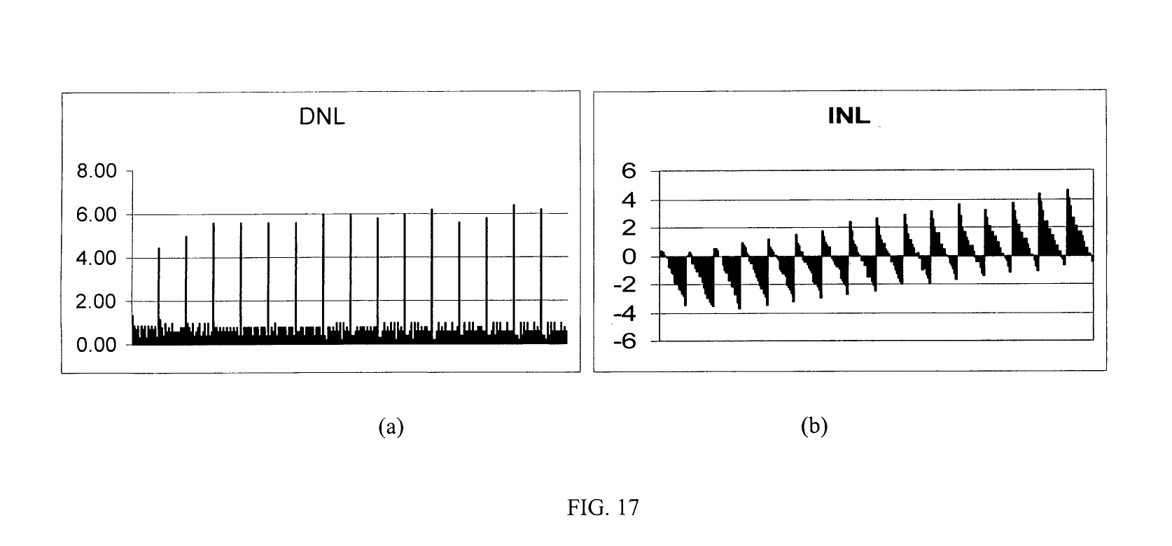

FIG. 16 shows the simulation results of an 8-bit current mode ADC that was developed as a case study in TSMC90 nm technology based on the architecture disclosed in this invention. The average sampling rate that was measured was higher than 40 MS/s given for the current comparator mentioned in the Description of Related Art section that was developed by Lin et al is used. The use of a faster and more accurate current comparator would significantly improve the sampling rate of the designed ADC. The DNL and INL errors are shown in FIG. 17a and FIG. 17b respectively. The most time consuming transition is when a change at the bit No. 4 occurs i.e., when the output changes from xxx01111 to xxx10000 and vice versa. In that case, the output is unstable for a long period of time and this transition determines the worse time needed for the 8-bit current mode ADC to settle. The Signal to Noise+Distortion Ration (SNDR) of the current mode ADC is higher than 35 dB if the input frequency is lower than 1 MHz.

In the context of this example, it was found that the area occupied by a 4-bit ADC implemented with small sized transistors was 1130 u². When cascode mirrors with 5 times larger transistors were used in order to achieve higher mismatch immunity the estimated area of an 8-bit ADC was about 0.06 mm². The average current consumption was 7 mA and the supply voltage when cascode current mirrors were used was 1.8V. When simple mirrors were used, then the average current consumption is 7 mA with 1V supply voltage.

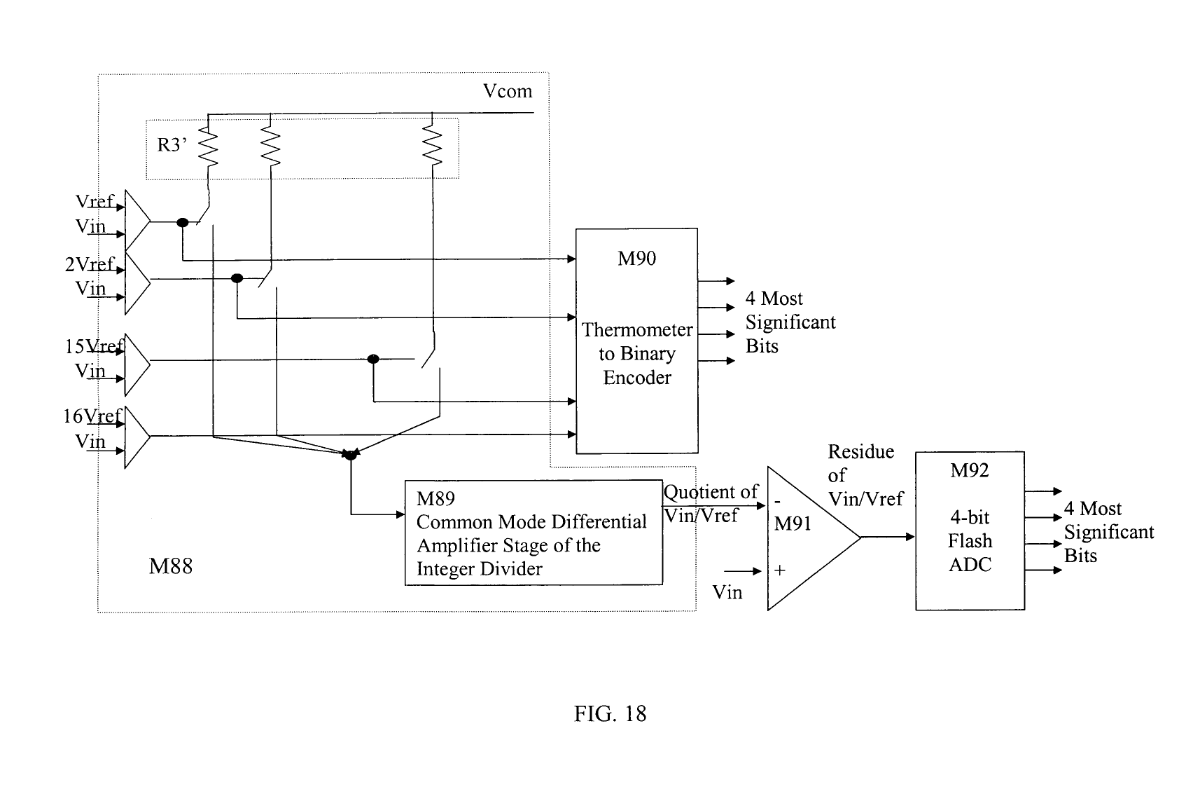

A voltage mode 8-bit ADC has also been tested based on the circuit of FIG. 18. The circuit comprises a VDIV16xVref component M88, a common mode differential amplifier stage M89, a thermometer to binary encoder M90, an amplifier M91 and a 4-bit Flash ADC M92. The VDIV16xVref component M88, and differential amplifier stage M89 form the circuit of FIG. 6c with the exception that outputs from each comparator are also send to encoder M90. The comparators of M88 are used as the input stage of a virtual 4-bit Flash ADC that consists of these comparators and the M90 encoder in order to avoid unnecessary redundancy

The voltage input is driven into the VDIV16xVref component M88. The outputs of these comparators connected to the M90 encoder generates the 4 most significant bits of the 8-bit voltage mode ADC.

The quotient output of the common mode differential amplifier stage M89 (the output of the circuit of FIG. 6c) is subtracted from the input Vin in M91 and the resulting residue is connected to the input of the 4-bit Flash ADC M92 that generates the 4 least significant bits of the 8-bit voltage mode ADC.

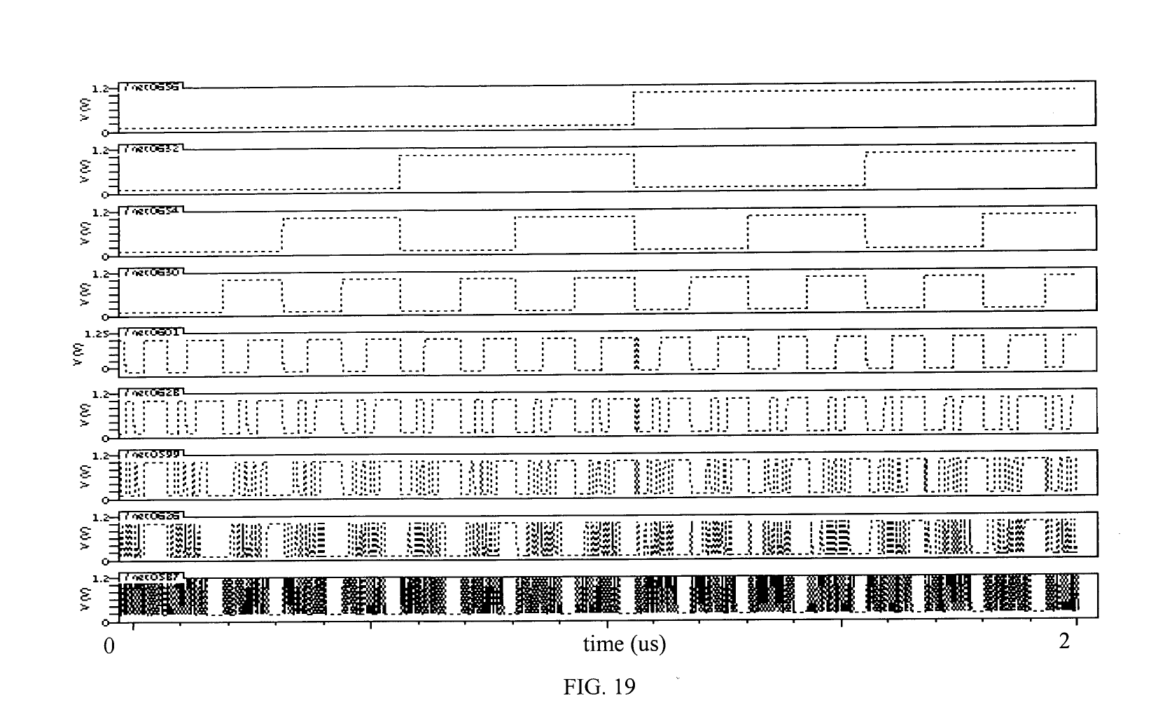

The simulated output of the 8-bit voltage mode ADC M86 is shown in FIG. 19. The linearity of the binary codes xxxx0000 and xxxx1111 of the 8-bit voltage mode ADC is similar to that of the 8-bit current mode ADC presented in FIG. 17. The linearity errors of these codes can be calibrated more easily using the current mode operation but in the voltage mode example, the linearity of the rest of the codes is better than that achieved by the current mode example. The sampling speed of the voltage mode ADC exceeds 1.5 GS/s and the SNDR is higher than 35 dB if the input frequency is lower than 5 MHz. The area occupied by this 8-bit voltage mode ADC is less than 0.05mm².

1. An analog to digital converter for converting an initial analog signal into a digital signal comprising
at least one electronic module with an input, a first output, and a second output, which module generates from an analog input signal:
a first output signal, which first output signal in terms of multiples of a predetermined amount of current or voltage, such as 1 uA or 1 mV, is substantially equal to the integer quotient of division of the input signal by a number or comprises a plurality of signals which if combined are substantially equal to the integer quotient of division of the input signal in terms of multiples of a predetermined amount of current or voltage, and
a second output signal which in terms of multiples of a predetermined amount of current or voltage, such as 1 uA or 1 mV, is substantially equal to the remainder of the division,
the analog to digital converter also comprising a further analog to digital converter for converting the second output signal into a digital signal, wherein the further analog to digital converter is connected the at least one module and
the module is configured so that in use when the analog input signal connects through the input the first output signal connects through the first output, and the second output signal connects through the second output into the further analog to digital converter.

2. A converter according to claim 1 wherein the further analog to digital converter comprising a Flash or Pipeline or Subrange or Counting or Sigma Delta or Algorithmic or Folding Interpolating analog to digital converter architecture

3. A converter according to claim 1 wherein the further analog to digital converter comprises a plurality of electronic modules with an input, a first output, and a second output, which modules generate from an analog input signal:
a first output signal, which first output signal in terms of multiples of a predetermined amount of current or voltage, such as 1 uA or 1 mV, is substantially equal to the integer quotient of division of the input signal by a number, wherein the further analog to digital converter comprises at least one module, and wherein at least some of the modules are configured in a tree formation connected together, the formation comprising
an input module with the first and second outputs each connected to a different module, the input module configured so that in use it takes the second output signal of the at least one module and sends the first and second output currents to the two connected modules,
and an output layer comprising at least two modules, one connected to a first output of another module and one to a second output of a module, wherein in use when the output signal of the modules of the output layer are mapped to a, value by comparison to a threshold value they provide the digital signal.

4. A converter according to any preceding claim comprising a second tree formation connected to the first output of the at least one module and comprising
an input module with the first and second outputs each connected to a different module, the input module configured so that in use it takes the first output signal of the at least one module and sends the first and second output signal to the two connected modules,
and an output layer comprising at least two modules, one connected to a first output of another module and one to a second output of a module, wherein in use when the output currents of the modules of the output layer are mapped to a, value by comparison to a threshold value they provide the digital signal, such that the combination of the at least one module and the first and second tree formation is a tree formation of modules.

5. A converter according to any preceding claim wherein for at least one, and preferably each, module the predetermined current or voltage for the first and second outputs is the same and/or wherein the predetermined current or voltage for a first or second output of one or more/each module is the same, or those predetermined currents are different by a known scaling factor, the known scaling factor used to ensure the division/analog to digital conversion

6. A converter according to any preceding claim wherein the number of the division is in the form 2^{x} where x is an integer.

7. A converter according to any preceding claim wherein if the output signals of a/each modules are mapped to a binary value by comparison to a threshold value the/each modules act as two bit resolution analog to digital converter of the input current received at that module's input.

8. A four bit resolution analog to digital converter comprising the converter of any preceding claim wherein the module to which the modules of the output layer is connected and from which the output layer receives input analog signals is the input module and the modules to which the first and second output signals of the input module are sent are modules of the output layer.

9. A converter according to any preceding claim wherein there is at least one intermediate layer of modules between the input layer and at least some/one of the modules of the output layer.

10. A converter according to claim 6 wherein there are a plurality of intermediate layers of modules between the input layer and at least some of the modules of the output layer.

11. A converter according to claim 6 or 7 wherein the output signal of the input layer and/or at least one and preferably each intermediate module provide multivalue digital representation of the input signal

12. A converter according to claim 9, 10 or 11 wherein the first intermediate layer comprising at least two modules each of the two taking an output signal from the input module to its input and any subsequent layers taking the output signals of the previous layer to its input and providing its output signals to the next layer which in the case of the last intermediate layer is the output layer.

13. A converter according to a preceding claim when dependent on claim 6 wherein integer x for the number used for division by a module is one greater than integer x for the number used for division by the modules connected to one or both of its outputs and/or x is equal to one for at least one and possibly all of the modules in the output layer.

14. A converter according to any preceding claim wherein the output layer comprises n/2 modules where n is the bits of resolution of the converter

15. A 2^{x} bit resolution converter where x is an integer comprising a converter according to any preceding claim wherein each layer comprises twice as many modules as the previous layer, the first after the input module comprising two modules.

16. A converter according to any of claims 1 to 14 wherein the resolution of the converter and/or the further analog to digital converter is not equal to 2^{x} at least one layer having less than twice and possibly the same number of modules as the previous layer, the number of modules between the input modules and modules of the output layer being different for different modules of the output layer.

17. A converter according to any of claims 3 to 16 comprising a mapper configured to map outputs signals (currents or voltages) of the modules of the output layer to a binary value by comparison to a threshold value to provide the binary digital signal.

18. A converter according to any preceding claim wherein one or more and preferably each module comprises an integer divider which divides an input current by the number, and provides the integer quotient, optionally a multiplier which multiplies an input current by the number of the division, and a subtractor which takes one input current from another, the components arranged so that in use the integer divider supplies the first output current (multiplier receives its input from the integer divider) and the subtractor receives it inputs from the multiplier or the integer divider, and from the module input.

19. An integer divider for finding the integer quotient of dividing by a number y, the divider comprising y−1 comparators and y−1 connected switches,
each comparator comparing an input signal to a multiple of a reference signal the multiple of the reference signal varying from one to y−1 for the comparators, and preferably including each integer in between,
the y−1 switches each connected to a comparator and a predetermined signal which depending on the output of the comparator either allow the predetermined signal to pass or do not,

20. An integer divider according to claim 19 wherein the input signal, reference signal and predetermined signal are an input current, reference current and predetermined current and
the output is combined from the predetermined current allowed to pass and is equal to the integer quotient of the input current divided by the number expressed in multiples of predetermined current.

21. An integer divider according to claim 20 wherein the predetermined current is the reference current divided in amplitude by y.

22. An integer divider according to claim 19 comprising a differential amplifier comprising a first input and a second input,
wherein the input signal, reference signal and predetermined signal are an input voltage, reference voltage and predetermined voltage the
and, the y−1 switches each connecting a resistor in parallel, to the first input of the differential amplifier,
the second input of the differential amplifier connected to a resistance, and
the resistance and the parallel resistors are connected to the same voltage,
so that the amplifier's voltage output is a multiple of a predefined reference voltage.

23. An integer divider according to claim 19, 20, 21 or 22 wherein the predetermined current or voltage is the reference current or voltage and/or, the predetermined current or voltage used is such that the integer quotient of the input current or voltage expressed in multiples of predetermined current or voltage is of same magnitude as input and/or is the result of a floor function applied to the input current or voltage

24. An integer divider for dividing by a number z where z=ab comprising a first integer divider according to any of claims 16 to 22 with a−1 comparators (where a is used in place of y) and a second comprising b−1 comparators (where b is used in place of y) connected together preferably so that the output of the first divider is added to the input signal and the added result is sent as the input signal of the second divider, the output signals of the first and second dividers being assed together to form the output signal of the overall integer divider.

25. An n bit analog to digital converter comprising an integer divider for finding the integer quotient of dividing by a number y, preferably according to any of claims 16 to 20, and at least one fewer than n (such as n/2) bit analog to digital converter.

26. An n bit analog to digital converter according to claim 25 wherein the quotient output of the integer divider is sent as an input to fewer than n bit analog to digital converter or a digital encoder and/or the quotient is subtracted from the input signal to form the remainder which is sent as an input to fewer than n bit analog to digital converter

27. A converter according to any of claims 1 to 18 wherein at least one and preferably each module comprises an integer divider in accordance with any of claims 19 to 26

28. An analog to digital converter for converting an initial analog voltage into a digital signal comprising a voltage to current converter and a converter according to any of claim 1 to 18 or 27.

29. An analog to digital converter comprising a binary tree of 2 bit resolution analog to digital converters with the inputs of some converters connected to the outputs of others.
